(19) United States
(12) Patent Application Publication
(10) Pub. No.: US 2001/0023136 A1
(43) Pub. Date: Sep. 20, 2001

(54) Method for fabricating gate oxide film of semiconductor device

(75) Inventors: Doo Young Yang, Seoul (KR); Chul Ju Hwang, Seongnam (KR)

Correspondence Address: OSTROLENK FABER GERB & SOFFEN, 1180 AVENUE OF THE AMERICAS, NEW YORK, NY, 100368403

(73) Assignee: Jusung Engineering Co., Ltd.

(21) Appl. No.: 09/808,274

(22) Filed: Mar. 14, 2001

(30) Foreign Application Priority Data
Mar. 16, 2000 (KR) 13323/2000

(51) Int. Cl. H01L 21/31; H01L 21/469; H01L 21/3205; H01L 21/4763

(52) U.S. Cl. 438/772; 438/771; 438/585

(57) ABSTRACT

A method for forming a gate oxide film includes the steps of: activating either one of deutrium and oxygen through remote plasma process; introducing deutrium and oxygen into a reactive chamber through a sufficiently isolated gas injection units; pyro-reacting deutrium and oxygen to form deuterium vapor; and heating a silicon wafer at an atmosphere of the deutrium vapor and forming a gate silicon oxide film of which silicon dangling bond on the silicon wafer surface makes a Si—D bonding. The silicon dangling bond existing at the interface between the silicon and the SiO₂ gate oxide film makes the Si—D bonding, stronger than Si—H bonding, to form the SiO2 film. Therefore, a gate oxide film having an excellent film quality can be formed. In addition, the oxidation is performed at a comparatively low temperature, so that the problem of difficulty in controlling a threshold voltage as the dopant doped at the lower portion of the gate oxide film is diffused outwardly is solved.

### BACKGROUND OF THE INVENTION

1. Field of the Invention

The present invention relates to a method for fabricating a semiconductor device, and more particularly, to a method for forming a gate oxide film having an excellent characteristics of hot carrier effect and threshold voltage.

2. Description of the Background Art

Currently, in case where a silicon wafer is used as a semiconductor substrate in the process of fabricating a semiconductor device, a silicon oxide (SiO₂) film is typically used as a gate insulation film. The gate insulation film is formed through a process in which a silicon wafer is heated at a high temperature at a vapor atmosphere which is formed by reacting oxygen and hydrogen by using an ignition torch, that is, through a pyro oxidation process.

As semiconductor devices are more highly integrated, the gate insulation film becomes thin. Thus, a gate insulation film needs to have an excellent characteristics of a hot carrier effect and a threshold voltage.

For example, when a SiO₂ film is formed as a gate insulation film on the silicon wafer by the pyro oxidation process, hydrogen bonding is much formed on the interface between the Si (wafer) and SiO₂ (gate insulation film).

In this respect, however, the hydrogen bonding is easily broken due to the high speed electron according to the hot carrier effect and a threshold voltage shift also occurs, having a bad influence on the device characteristics.

This phenomenon is anticipated to become more serious in a process of fabricating a semiconductor device of which a design rule is below 0.18 μm.

Therefore, efforts are being actively made to heighten a reliability of a device by improving the method for forming the existing gate insulation film. One of them is to control the Si/SiO₂ interface state and a charge trap of SiO₂ in the process of forming the SiO₂ gate insulation film.

In the case of forming SiO₂ gate insulation film by the pyro oxidation using oxygen and hydrogen, it is difficult to drop the temperature to below 800° C. in view of the process characteristics, which goes against the recent tendency of fabricating a semiconductor device at a comparatively low temperature and a dopant doped at the lower portion of the gate insulation film is diffused externally, making it difficult to control the threshold voltage.

An article, IEEE Electron Device Letter, Vol. 18, No. 3, March, pp 81-83, 1997, discloses the control of the Si/SiO₂ interface state. According to the article, after a semiconductor device is completely fabricated, when it is annealed at the deutrium (D₂) atmosphere at the final stage, a silicon dangling bond existing on the interface between the Si/SiO₂ forms an Si-D bonding, heightening the reliability of the device.

However, after fabrication of the device, when the device is actually subject to annealing with deutrium as disclosed in the article, deutrium fails to transmit the Si₃N₄ layer which is typically used as a passivation layer. Thus, it is ineffective.

In addition, for the D₂ annealing, the semiconductor device needs to be heated at a high temperature. In this case, however, the dopant doped at the lower portion of the gate insulation film is diffused externally, resulting in that it is difficult to control the threshold voltage and form a shallow junction.

### SUMMARY OF THE INVENTION

Therefore, an object of the present invention is to provide a method for forming a gate oxide film of a semiconductor device in which a silicon dangling bond existing at the interface between a silicon substrate and a SiO₂ gate oxide film makes a Si—D bonding to form an SiO₂ film at a comparatively low temperature.

To achieve these and other advantages and in accordance with the purpose of the present invention, as embodied and broadly described herein, there is provided a method for forming a gate oxide film including the steps of: activating either one of deutrium and oxygen through remote plasma process; introducing deutrium and oxygen into a reactive chamber through a sufficiently isolated gas injection units; pyro-reacting deutrium and oxygen to form deuterium vapor; and heating a silicon wafer at an atmosphere of the deutrium vapor and forming a gate silicon oxide film of which silicon dangling bond on the silicon wafer surface makes a Si—D bonding.

In the method for fabricating a gate oxide film of the present invention, preferably, the silicon wafer is mounted on a suscepter, a heater for heating the silicon wafer is inserted in the suscepter, and a chamber heater for rising the temperature of the reactive chamber is provided outside the reactive chamber.

In the method for fabricating a gate oxide film of the present invention, the wafer is maintained constantly at a temperature in the range of 500˜700° C. in the step of forming the gate silicon oxide film.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a sectional view of a semiconductor device fabricating apparatus in accordance with the present invention.

### DETAILED DESCRIPTION OF THE PREFERRED EMBODIMENTS

Reference will now be made in detail to the preferred embodiments of the present invention, examples of which are illustrated in the accompanying drawings.

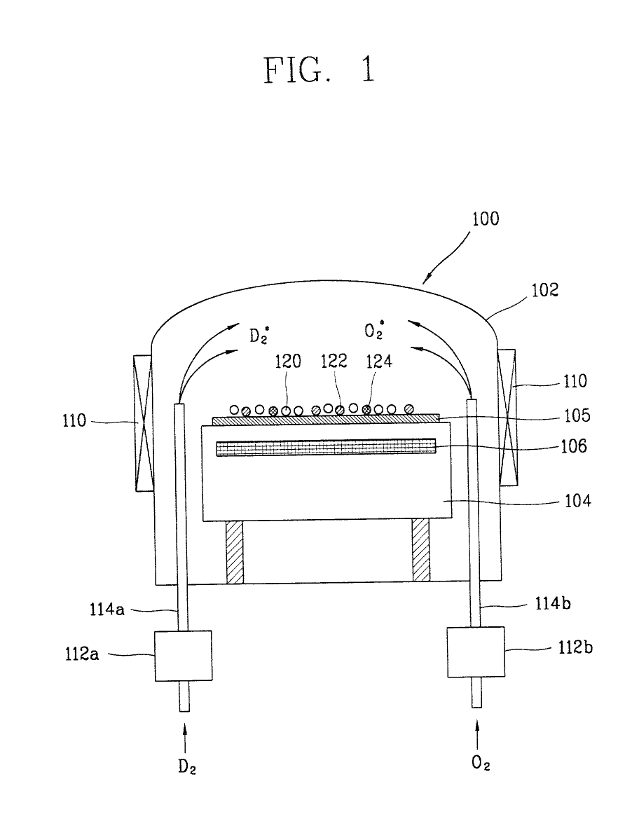

FIG. 1 is a sectional view of a semiconductor device fabricating apparatus in accordance with the present invention.

As shown in the drawing, D₂ and O₂ as gases for pyro oxidation are respectively injected into the chamber 102 through the supply tubes 114a and 114b.

A remote plasma generators 112a and 112b are disposed at the middle portion of the supply tubes 114a and 114b to activate D₂ and O₂ to be D₂* and O₂*.

Even though the gas supply tubes 114a and 114b are isolated at a distance with each other, since D₂* and O₂* injected in the chamber 102 are in the active state, they are reacted with each other even without an ignition torch, most of which turns to vapor 120 of D₂O. A very small amount of D₂* 124 and O₂* 122, which have not been reacted, remain to stimulate oxidation on the surface of the silicon wafer 105 mounted on the suscepter 104.

In the process of forming a gate silicon oxide film of the present invention, D₂O vapor increases the solubility of O₂ for the silicon wafer to thereby heighten the growth rate of the oxide film, and the D₂* 124, which has not been reacted with the O₂* 122, generates a low temperature D₂* annealing effect for the silicon wafer.

The oxidation process is a surface state reaction in which the activated D₂* 124 and O₂* participate. Thus, an excellent film quality is maintained even though the gate silicon oxide film is formed at a low temperature, compared with the conventional pyro oxidation which uses only H₂ and O₂. Also, since the growth rate of the oxide film is high, a sufficient thickness of oxide film can be formed even at a comparatively low temperature.

Accordingly, even in the case that the silicon wafer 105 is heated by using the chamber heater 110 attached at the outer wall of the chamber and the heater 106 inserted at the lower portion of the suscepter, the pyro oxidation can be performed in a state that the temperature of the wafer is maintained at the temperature of 650° C., lower than the temperature in pyro oxidation of the conventional art where only H₂ and O₂ are used.

As so far described, according to the method for forming a gate oxide film of a semiconductor device, the silicon dangling bond existing at the interface between the silicon and the SiO₂ gate oxide film makes the Si—D bonding, stronger than Si—H bonding, to form the SiO₂ film, so that a gate oxide film having an excellent film quality can be formed. In addition, the oxidation is performed at a comparatively low temperature, so that the problem of difficulty in controlling a threshold voltage as the dopant doped at the lower portion of the gate oxide film is diffused outwardly is solved.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalence of such meets and bounds are therefore intended to be embraced by the appended claims.

What is claimed is:

1. A method for forming a gate oxide film comprising the steps of:
activating either one of deutrium and oxygen through remote plasma process;
introducing deutrium and oxygen into a reactive chamber through a sufficiently isolated gas injection units;
pyro-reacting deutrium and oxygen to form deuterium vapor; and
heating a silicon wafer at an atmosphere of the deutrium vapor and forming a gate silicon oxide film of which silicon dangling bond on the silicon wafer surface makes a Si—D bonding.

2. The method of claim 1, wherein the silicon wafer is heated by using a heater inserted in the suscepter.

3. The method of claim 1, wherein heating the silicon wafer refers to heating the inside of the reactive chamber by using a chamber heater installed at the outer wall of the reactive chamber.

4. The method of claim 1, wherein, in the step of heating the silicon wafer, the wafer is maintained at a predetermined temperature in the range of 500˜700° C.
